(19) United States
(12) Patent Application Publication
(10) Pub. No.: US 2024/0347313 A1
(43) Pub. Date: Oct. 17, 2024

(54) SYSTEMS AND METHODS OF CLEANING ELECTRON SOURCES IN CHARGED-PARTICLE BEAM SYSTEMS

(71) Applicant: ASML NETHERLANDS B.V., Veldhoven (NL)

(72) Inventors: Zhidong DU, San Jose, CA (US); Xuedong LIU, San Jose, CA (US)

(73) Assignee: ASML NETHERLANDS B.V., Veldhoven (NL)

(21) Appl. No.: 18/751,031

(22) Filed: Jun. 21, 2024

Related U.S. Application Data
(63) Continuation of application No. PCT/EP2022/083068, filed on Nov. 24, 2022.
(60) Provisional application No. 63/293,615, filed on Dec. 23, 2021.

(51) Int. Cl. H01J 37/22

(52) U.S. Cl. CPC H01J 37/22; H01J 2237/022

(57) ABSTRACT

Systems and methods of removing a contaminant from an emitter tip of an electron source in an electron beam apparatus are disclosed. An electron beam apparatus may include an electron source comprising an emitter tip configured to emit electrons and an optical source configured to generate an optical beam illuminating a portion of the emitter tip to excite a surface mode of the optical beam, wherein the excited surface mode facilitates removal of a contaminant from a surface of the illuminated portion of the emitter tip. The excited surface mode may comprise a propagating surface wave or a localized surface wave. The emitter tip may comprise a grating structure, wherein a characteristic of the grating structure matches a wavevector of the optical beam.

### CROSS-REFERENCE TO RELATED APPLICATIONS

This application claims priority of International application PCT/EP2022/083068, filed on 24 Nov. 2022, which claims priority of U.S. application 63/293,615, filed on Dec. 23, 2021. These applications are incorporated herein by reference in their entireties.

### TECHNICAL FIELD

The embodiments provided herein relate to electron sources of charged-particle beam systems, and more particularly to systems and methods of cleaning field-emission electron sources using an optical source.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy, imaging resolution and yield in defect detection become more important. Multiple charged-beams may be employed to address the inspection throughput requirements; however, imaging resolution of multiple charged-beam systems may be compromised, rendering the inspection tools inadequate for their desired purpose. Imaging resolution is also influenced by electron source stability, which is maintained by periodically decontaminating the electron emitter tips. The existing procedures for cleaning the electron emitter tips of the electron sources may necessitate a partial or a complete shutdown of an inspection tool, affecting an overall inspection throughput, among other issues.

Thus, related art systems face limitations in, for example, image resolution and electron source stability due to contamination of the electron source. The existing ways of removing contaminants from the electron source may introduce variability in the current generated after cleaning or shorten the life-span of the electron source, rendering them cost-ineffective or unreliable, or both. Therefore, systems and methods of cleaning an electron source while maintaining the imaging resolution, source stability, and inspection throughput are desired.

### SUMMARY

Some embodiments of the present disclosure are directed to an electron beam apparatus comprising an electron source and an optical source. The electron source may comprise an emitter tip configured to emit electrons and the optical source may be configured to generate an optical beam illuminating a portion of the emitter tip to excite a surface mode of the optical beam, wherein the excited surface mode facilitates removal of a contaminant from a surface of the illuminated portion of the emitter tip.

Some embodiments of the present disclosure are directed to an electron beam apparatus comprising an electron source and an optical source. The electron source may comprise an emitter tip configured to emit electrons and the optical source may be configured to generate an optical beam illuminating a portion of the emitter tip to remove a contaminant from a surface of the illuminated portion of the emitter tip.

Some embodiments of the present disclosure are directed to a method of removing a contaminant from an emitter tip of an electron source. The method may comprise activating an optical source to generate an optical beam and illuminating a portion of the emitter tip with the optical beam excite a surface mode of the optical beam, wherein the excited surface mode facilitates removal of a contaminant from a surface of the illuminated portion of the emitter tip.

Some embodiments of the present disclosure are directed to a method of removing a contaminant from an emitter tip of an electron source. The method may comprise activating an optical source to generate an optical beam and illuminating a portion of the emitter tip with the optical beam to remove the contaminant bonded to a surface of the illuminated portion of the emitter tip.

Some embodiments of the present disclosure are directed to a non-transitory computer readable medium storing a set of instructions that is executable by one or more processors of an electron beam apparatus to cause the electron beam apparatus to perform a method of removing a contaminant from an emitter tip of an electron source. The method may comprise activating an optical source to generate an optical beam and illuminating a portion of the emitter tip with the optical beam excite a surface mode of the optical beam, wherein the excited surface mode facilitates removal of a contaminant from a surface of the illuminated portion of the emitter tip.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIG. 3 illustrates a schematic diagram of an exemplary arrangement of an electron source, consistent with embodiments of the present disclosure.

FIGS. 4A and 4B illustrate schematic diagrams of an emitter tip of the electron source cleaned using a photon-contaminant resonance mechanism, consistent with embodiments of the present disclosure.

FIGS. 5A and 5B illustrate schematic diagrams of an emitter tip of the electron source cleaned using a localized optical radiation heating mechanism, consistent with embodiments of the present disclosure.

FIG. 6 is a process flowchart representing an exemplary method 600 of removing a contaminant from the emitter tip of an electron source using an optical source, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

Obtaining high resolution images with a SEM starts with an electron source that has high brightness, a small energy spread, and a small virtual size. Thermionic emission sources, such as tungsten hairpin filaments, although inexpensive and easy to use, suffer from several drawbacks including short lifetime, high operating temperature, low brightness, broad beam energy spread, among other things, which may result in reduced image quality. In comparison, field-emission sources provide superior brightness due to substantially smaller emission area, small beam energy spread, high longevity, and high image resolution, rendering them a desirable electron source for high resolution imaging in SEMs. However, there are several issues that may limit their efficiency and usability in systems and applications requiring high throughput. Some of these issues include short current-decay time (<100 hours) even at high vacuum conditions, large emission-current variation, and ultra-high or extremely high vacuum requirements to prevent arc-over at the emitter tip.

To mitigate some of the existing issues with the field-emission sources, the electron source is cleaned periodically, such as by resistively (ohmically) heating the electron source periodically to clean the emission surface, or indirectly heating the electron emission source through radiation from resistively heating a filament placed in the vicinity of the electron source. In resistive heating, also known as “flashing” or “flash heating.” large electric current may be passed through the filament and the emitter tip, raising the temperature globally, to decontaminate the emission surface and restore the emission current. Flashing may include mild-heating or hard heating, raising the temperature of the electron source, including the non-emission surfaces, in a range from 700° C. to 2000° C. If a hard-heating procedure is performed, the inspection tool may have to be shut down and the electron optical column may have to be realigned or recalibrated, thereby significantly impacting the throughput. A mild-heating procedure may be performed more frequently to prolong the period between two hard-heating procedures.

In either of the flashing techniques, the inventors of this disclosure have realized that the outgassing due to global temperature increase is significant enough to negatively affect the vacuum in the chamber enclosing the electron source, and in particular, around the electron emitter tip. One of several issues with poor vacuum around the emitter tip is an appreciable reduction in the lifetime of the electron source due to higher rate of contaminant formation on its surface, which would necessitate more and frequent flashing cycles, causing tip blunting and frequent tip replacement. In some cases, the outgassing may be severe enough to “strain” the vacuum pumping mechanism enough to cause longer machine downtime, thereby negatively affecting the throughput as well. Therefore, it may be desirable to remove contaminants from the emission surface of an electron source, while maintaining low outgassing rates and high inspection throughput.

In some embodiments of the present disclosure, an electron beam apparatus comprising an electron source and an optical source is disclosed. The electron source may include an emitter tip configured to generate electrons and the optical source may be used to generate an optical beam to illuminate the emitter tip to remove contaminants adsorbed on the emitter tip. With optical beams, such as a laser beam, the wavelength may be adjusted based on the target contaminant and the beam may be focused on a smaller portion of the tip, such as the apex of the emitter tip. Even if the desired wavelength of the laser beam, such as infrared laser, causes the emitter tip to heat up, the amount of heat generated is appreciably less, resulting in significantly reduced outgassing in the vacuum chamber, and which may also minimize tip blunting. This is in contrast to the existing techniques and prior art, which heat up the entire emitter tip either by passing current through the tip or by heating a filament close to the tip to remove contaminants. Further, the laser beam may be linearly polarized such that the removal of the contaminants may be assisted by the electric field component of the laser beam, further reducing the amount of heat generated.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A. or B, or A and B. As a second example, if it is stated that a component may include A, B, or C, then, unless specifically stated otherwise or infeasible, the component may include A, or B, or C, or A and B, or A and C, or B and C, or A and B and C.

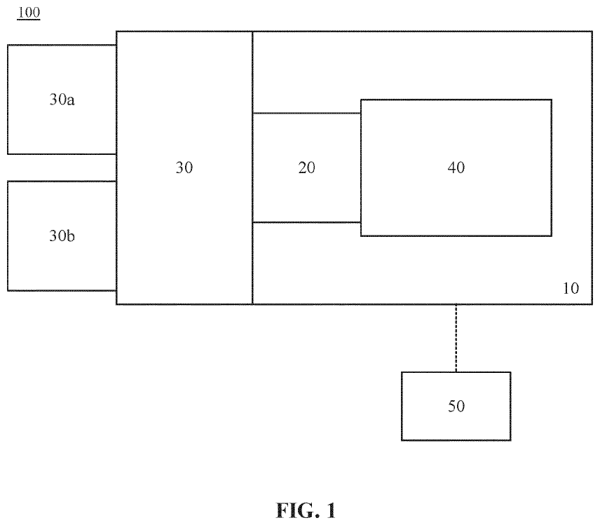

Reference is now made to FIG. 1, which illustrates an exemplary electron beam inspection (EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles and charged-particle beam apparatuses. For example, a charged-particle may refer to an electron, an ion, or any positively or negatively charged particle and a charged-particle beam apparatus may refer to an electron beam apparatus, or an ion beam apparatus, or any apparatus using electrons and ions such as a SEM, or a focused ion beam (FIB) in combination with SEM.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

In some embodiments, controller 50 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 50 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

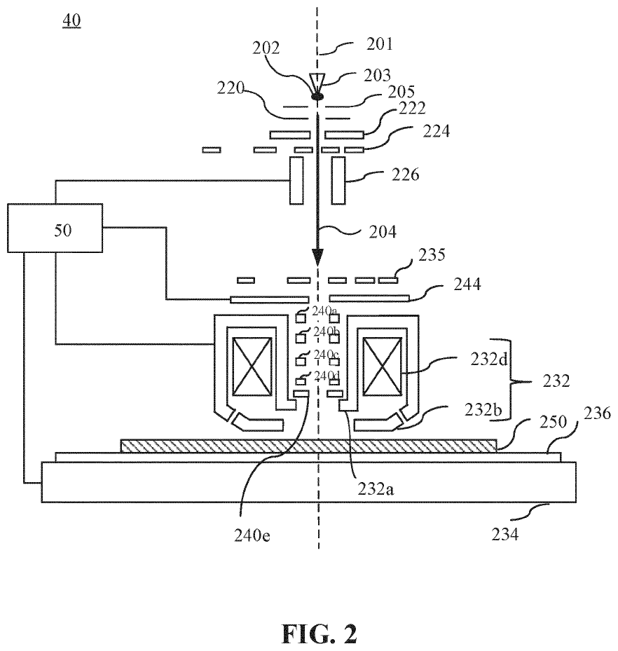

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240c, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest.

In objective lens assembly 232, exciting coil 232d and pole piece 232a may generate a magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232 and control focusing situation of signal electron beams for high detection efficiency, or avoid arcing to protect sample. One or more deflectors of beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a-e may be different in different embodiments.

Backscattered electrons (BSEs) and secondary electrons (SEs) can be emitted from the part of sample 250 upon receiving primary electron beam 204. A beam separator (not shown) can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of wafer sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

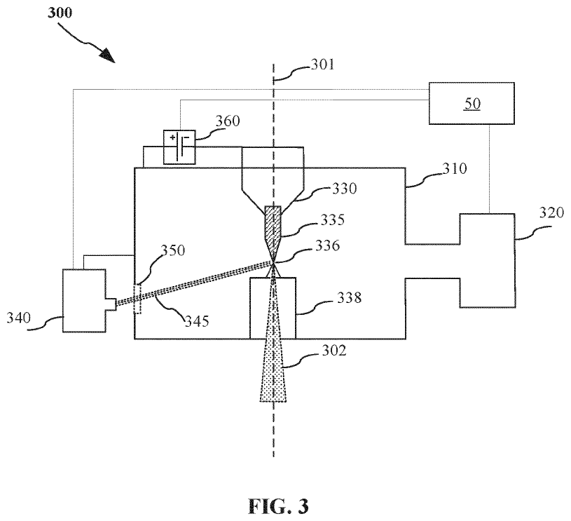

An exemplary configuration 300 of an electron source in an electron beam inspection tool is illustrated in FIG. 3, consistent with embodiments of the present disclosure. In configuration 300, apparatus 40 may comprise a chamber 310 comprising a view port 350, a vacuum pumping mechanism 320, an electron source 330 having an emitter tip 335, an extractor electrode 338, an optical source 340, a power supply 360, and a controller 50.

In some embodiments, chamber 310 may comprise a vacuum chamber and may be a part of electron-optics column (not shown) of apparatus 40. Chamber 310 may enclose electron source 330 and extractor electrode 338. Chamber 310 may be constructed from a high-vacuum or UHV compatible material such as, but not limited to, stainless steel, and may be evacuated using one or more vacuum pumps of vacuum pumping mechanism 320. In some embodiments, chamber 310 may be pumped to ultra-high vacuum (UHV) or extreme high vacuum (XHV) conditions to provide a long mean free path for the electrons traveling downstream in the electron-optics column, to improve the reliability and stability of electron sources, to prolong the operating lifetime of electron sources, among other advantages.

In some embodiments, chamber 310 may include a view port 350 configured to allow an optical beam 345 generated by an optical source 340 to pass through. View port 350 may be mounted on an exterior surface of chamber 310 such that optical beam 345 passing through may be incident on emitter tip 335 without hinderances. In some embodiments, view port 350 may be made from a material substantially transparent to a broad range of wavelengths of electromagnetic radiation. For example, view port 350 may be made from borosilicate glass having an optical transmission greater than 90% over a wavelength range of 375 nm to 1900 nm. It is to be appreciated that other materials with desirable characteristics may be used as well, as appropriate. In some embodiments, in addition to being substantially transparent, view port 350 may be made from a low outgassing material compatible with high-vacuum or UHV operating conditions.

Vacuum pumping mechanism 320 may be in fluidic connection with chamber 310 such that chamber 310 may be evacuated efficiently. In some embodiments, vacuum pumping mechanism 320 may comprise a plurality of vacuum pumps including, but not limited to, a diaphragm pump, a scroll pump, an adsorption pump, a diffusion pump, a turbomolecular pump, a cryogenic pump, an ion getter pump, a titanium sublimation pump, among other vacuum pumps. In operation, one or more pumps may be used in combination to achieve the desired vacuum levels. In some embodiments, the choice of vacuum pumps or combinations of vacuum pumps may be based on factors including, but not limited to, the end-use application, the gases to be evacuated, the surfaces that contribute to outgassing, or the desired vacuum levels.

In currently existing SEMs, an electron source may include a thermionic emission source or a field-emission source. In general, thermionic emission sources rely on resistive heating to generate electrons from a cathode such as a tungsten filament, a LaB₆, or a CeB₆ crystal. Large currents are passed through the filament (cathode), generating heat based on the resistance of the filament, and thereby providing energy to the electrons to escape the solid surface. Although cheap and easy to maintain, such sources of electrons suffer from low brightness and broad energy distribution, resulting in inadequate image quality. On the other hand, field emission sources use an electrostatic field to induce electron emission. This electrostatic field is applied to an apex of an emitter tip made of an electrically conducting wire, where quantum mechanical tunneling allows high-energy electrons to be released. The emission area is substantially smaller for a field-emission source, typically in nanometers, than a thermionic source, resulting in superior brightness and, in turn, enhanced image quality including higher spatial resolution and increased signal to noise.

In some embodiments, apparatus 40 may include electron source 330, which comprises a field-emission source, also referred to as a field-emission gun (FEG) or a cold field emitter. Electron source 330 may include emitter tip 335 attached to a filament and shaped to have a tapered end. An apex 336 of the tapered end of emitter tip 335 may be sharpened to a tip radius of 0.5 μm or less, 0.4 μm or less, 0.3 μm or less, 0.2 μm or less, or 0.1 μm or less, such that the electrostatic field is extremely high, in the order of 10⁸ V/cm, facilitating “quantum tunneling” of electrons. The emission current in a field-emission source is purely due to tunneling and is temperature-independent.

For a field emitter such as electron source 330, it may be desirable to have a clean emitter tip surface, essentially free of contaminants and adsorbates. One of several ways to maintain a clean emitter tip surface includes maintaining high levels of vacuum, and in some cases, extremely high vacuum around electron source 330. As an example, at a negative pressure of 106 Torr, a monolayer of gas is adsorbed on an exposed surface every 1-2 seconds. Although the monolayer formation rate may be prolonged to 5-10 minutes, for example, by operating at vacuum conditions of 10⁻¹⁰ Torr or below, the monolayer formation rate may still be unacceptable, rendering the tool and the inspection process inefficient.

Some of the currently existing techniques of cleaning emitter tip surfaces include a “flashing” process that involves resistively heating the emitter tip and the supporting filament to which the emitter tip is attached, by passing current through the emitter tip, to temperatures ranging from 700° C. to 2000° C. for short periods. While mild flashing may be performed at lower temperatures and more frequently compared to hard flashing, which is performed at higher temperatures and may require tool shut-down, the flash heating technique has several disadvantages and challenges. Some of the challenges include, but are not limited to, higher outgassing due to appreciable overall temperature increase of the chamber, temporary reduction of vacuum levels allowing re-adsorption of contaminants on the emitter tip, reduction in operating lifetime of the electron source, emission current instability, or short current-decay time of the electron source, among other issues. Other techniques may include radiative heating of a filament positioned in the vicinity of the emitter tip; however, radiative and resistive heating include heating procedures that increase the outgassing rate or high-voltage breakdown risk, or both. Therefore, it may be desirable to clean the field-emission source emitter tips with a technique that may mitigate one or more issues associated with existing cleaning techniques, while maintaining imaging resolution and inspection throughput.

As illustrated in FIG. 3, emitter tip 335 of electron source 330 may be illuminated with optical beam 345 generated by optical source 340. In some embodiments, optical source 340 may comprise a source of photons including, but not limited to, a laser, a high intensity laser, or a monochromatic light source. In some embodiments, optical source 340 may comprise an adjustable laser source, configured to be controlled by controller 50. Controlling optical source 340 may include, but is not limited to, activating the laser source, calibrating and stabilizing the laser source, directing the photons along an optical axis, adjusting a wavelength, a frequency, a duty-cycle, or an intensity of the optical beam, etc. An adjustable laser source may be used to generate optical beam 345 having an adjustable wavelength, for example, based on the target contaminant to be removed. In some embodiments, optical beam 345 may be a continuous laser beam or a pulsed laser beam.

In some embodiments, optical source 340 may be fixedly coupled with chamber 310 such that optical beam 345 generated from optical source 340 may pass through view port 350 and be incident on a portion of the tapered end of emitter tip 335. In some embodiments, optical beam 345 may be aligned to illuminate apex 336 of emitter tip 335 such that upon illumination, one or more contaminants may be dislodged from the exposed surface of emitter tip 335, rendering the surface substantially clean from contaminants or adsorbates. Once aligned, the fixed coupling between optical source 340 and chamber 310 may ensure that the alignment is maintained until a replacement of emitter tip 335 is warranted, or a scheduled tool maintenance needs to be performed. In some embodiments, optical source 340 may comprise a beam polarizer (not shown). Beam polarizer may be configured to polarize optical beam 345 generated by optical source 340. In some embodiments, optical beam 345 may be linearly polarized, circularly polarized, elliptically polarized, or randomly polarized. Polarization of a beam, for example a light beam, as used herein, refers to the direction of the electric field oscillation of the light beam. For example, in a linearly polarized light beam, the electric field oscillates in a linear direction perpendicular to the propagation axis of the light beam, and the magnetic field oscillates in a direction perpendicular to the propagation axis of the light beam and to the electric field direction.

In some embodiments, although not illustrated, apparatus 40 may include more than one optical source 340 configured to illuminate emitter tip 335 with optical beams such as optical beam 345. The plurality of optical sources 340 may be positioned such that the plurality of optical beams may be incident on apex 336 of emitter tip 335 at different locations around the axis of emitter tip 335. It is to be appreciated that a configuration comprising more than one optical source 340 may also comprise a corresponding view port 350 for a corresponding optical beam to pass through. In some embodiments, the number of optical sources employed may be determined based on the mechanical, structural, spatial, or functional design considerations of chamber 310.

In some embodiments, optical beam 345 may be incident on apex 336 or on regions close to apex 336 of emitter tip 335 at an incidence angle between 0° to 90° with respect to axis of emitter tip 335, which may substantially coincide with primary optical axis 301. The incidence angle of optical beam 345 may be determined based on the location of optical source 340, path of optical beam 345, location of view port 350, position of emitter tip 335 within chamber 310, among other things.

In some embodiments, in a configuration comprising multiple optical sources 340, two or more optical sources 340 may be configured to illuminate emitter tip 335 with optical beams of similar or dissimilar characteristics such as, but not limited to, wavelength, frequency, intensity, power density, incidence angle, among other characteristics. For example, a first optical source may generate a first optical beam in the ultraviolet wavelength range at a 45º incidence angle on a first portion of the emitter tip, and a second optical source may generate a second optical beam in the infrared wavelength range at a 30º incidence angle on a second portion of the emitter tip. A characteristic of optical beam 345 may be determined based on the contaminant, type of bonding between the contaminant and the surface of emitter tip 335, location of the contaminant on or around apex 336 of emitter tip 335, among other things. One or more optical beams 345 from a corresponding optical source 340 may be incident on emitter tip 335 simultaneously or substantially simultaneously. In some embodiments, multiple optical beams may illuminate emitter tip 335 sequentially with a regular or an irregular timing offset between successive incidences. One of several advantages of illuminating emitter tip 335 with multiple optical beams from multiple optical sources simultaneously includes improved cleaning efficiency and enhanced throughput by reducing the time required to clean emitter tip 335.

In operation of apparatus 40 for inspection or imaging, power supply 360 may be configured to generate electrostatic field to extract electrons from emitter tip 335, or configured to focus the extracted electrons, or both. The extracted electrons may form an electron beam 302 traveling along primary optical axis 301. In some embodiments, power supply 360 may be controlled by controller 50. Controlling power supply 360 may include adjusting the voltage, the current, or the power generated by power supply 360 to regulate the electron beam characteristics including, but not limited to, number of electrons, electron beam distribution, among other things.

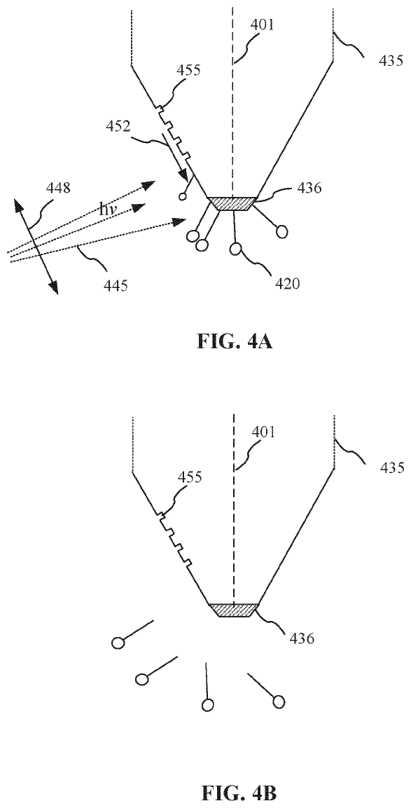

Reference is now made to FIGS. 4A and 4B, which illustrate schematic diagrams of an exemplary apex of emitter tip cleaned using a photon-contaminant resonance mechanism, consistent with embodiments of the present disclosure. FIGS. 4A and 4B illustrate an apex 436 of an emitter tip 435, one or more contaminants 420 bonded to a surface of emitter tip 435, and an optical beam 445 illuminating a portion of apex 436. It is to be appreciated that emitter tip 435 and apex 436 may be substantially similar to and may perform substantially similar functions as emitter tip 335 and apex 336 of FIG. 3.

As shown in FIG. 4A, optical beam 445 generated from an optical source (e.g., optical source 340 of FIG. 3) such as a laser, may be directed to illuminate a portion of apex 436. In some embodiments, illuminating of a portion of a surface of apex 436 with optical beam 445 may cause breakage of a bond between contaminant 420 and surface of apex 436, rendering the surface of emitter tip 435 clean and substantially devoid of contaminants. In some embodiments, contaminant 420 may comprise an adsorbate, a gas molecule, an atom, a molecule, a physically bonded atom or molecule, a chemically bonded atom or molecule, or debris, or any combination thereof. In some embodiments, a plurality of contaminants 420 may comprise a monolayer formed on a portion of the surface of emitter tip 435. Contaminant 420 may include a carbon atom, carbon monoxide, carbon dioxide, water molecule, an organic molecule, or an inorganic molecule. Adsorbates, as referred to herein, include atoms or molecules that may be physically adsorbed on a surface by van der Waals interactions or other intermolecular forces.

In some embodiments, optical beam 445, upon illuminating a portion of apex 436, may break the bond between one or more contaminants 420 and the surface of emitter tip 435. Breaking the bond may include desorption of adsorbed molecules, or cleavage of a physical or a chemical bond, or dissociation of a molecule into individual atoms before removal from the surface. In some embodiments, breaking the bond may include a photon-assisted quantum process, also referred to as photon-contaminant resonance, to remove atoms or molecules from a surface. In the example shown in FIG. 4A, optical beam 445 comprising photons having an energy hν, may impart the energy required for an atom to break the bond with the surface of emitter tip 435. In some embodiments, optical beam 445 may be focused on a small area such that only contaminants 420 in the illuminated area of apex 436 may be removed. Increasing the illumination area by defocusing optical beam 445 may enlarge the target area of apex 436 to clean a larger surface area.

In some embodiments, a photon-contaminant resonance mechanism for cleaning emitter tips may include adjusting a wavelength of optical beam 445 comprising photons to break the bond between contaminant 420 and the surface of emitter tip 435 or apex 436. The wavelength may be adjusted to be resonant with the bond formed between contaminant 420 and surface of emitter tip 435.

In some embodiments, breaking the bond to remove contaminant 420 from surface of apex 436 by photon-contaminant resonance mechanism may generate heat based on characteristics of optical beam 445 such as power, wavelength, frequency, duration of exposure, intensity, target material, target contaminant, or type of bond between the contaminant and the surface of the emitter tip, among other factors. However, the amount of heat generated may be considerably less compared to the existing techniques of resistive or radiative heating to clean emitter tips of electron sources. FIG. 4B illustrates a surface of apex 436 of emitter tip 435 substantially devoid of contaminant 420 upon illumination by optical beam 445 having a wavelength in resonance with the contamination bond. One or more contaminants 420, upon being released in the chamber space may be evacuated by pumping mechanism (e.g., vacuum pumping mechanism 320 of FIG. 3). The number of contaminants released by a photon-assisted quantum cleaning process may be significantly lower compared to that of a resistively or radiatively heating cleaning process. This may be because optical beam 445 may be targeted locally to a smaller spot to selectively expose apex 436 from where electrons may be emitted compared to a global heating of the filament and emitter tip in a flash heating process, which causes excessive outgassing and resultantly reduction of vacuum levels.

In some embodiments, propagation of an optical beam or a light beam may be considered as a wave phenomenon where light waves may be recognized as electromagnetic transverse waves. In electromagnetic transverse waves, the electric field and the magnetic field oscillate orthogonal to each other and to the direction of the propagation of the light wave. A light beam may be linearly polarized, circularly polarized, elliptically polarized, or randomly polarized.

Turning back to FIG. 4A, optical beam 445 may comprise a linearly polarized optical beam such that the electric field 448 oscillates in a direction perpendicular to the propagation of optical beam 445 and substantially parallel to the tapering edge of emitter tip 435. In some embodiments, one or more portions of the tapering edge of emitter tip 435 may comprise a grating structure 455. The characteristics of grating structure 455 may be adjusted to match or based on a wavevector of optical beam 445. The wavevector may include a wavenumber, an angular wavenumber, wavelength, direction of wave propagation, among other things. The characteristics of grating structure 455 may include, but is not limited to, pitch, spacing, height, width, angle of the gratings, etc.

In some embodiments, a surface mode of linearly polarized optical beam 445 may be excited upon illumination of a surface of emitter tip 435 including grating structure 455. The surface mode of linearly polarized optical beam 445 may comprise a propagating surface wave 452, which may enhance optical energy absorption, upon irradiation of emitter tip 435. Propagating surface wave 452, propagating along grating structure 455 on tapered edge of emitter tip 435 may enable debonding of contaminant 420 from surface of emitter tip 435. Propagating surface wave 452 may be excited upon incidence of linearly polarized optical beam 445 on grating structure 455. One of several advantages of the propagating surface wave of optical beam 445 includes reduction in reflected or scattered photons from emitter tip 435 and thereby reducing outgassing from neighboring regions of emitter tip 435. Although not illustrated, it is to be appreciated that grating structure 455 may be formed on one or more surfaces of emitter tip 435. In some embodiments, grating structure 455 may be formed on a small region on or around apex 446. Alternatively, or additionally, grating structure 455 may be formed on a majority of the tapered edges of emitter tip 435.

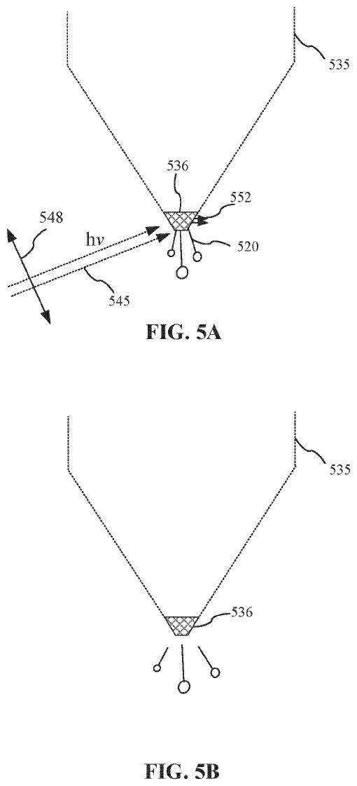

Reference is now made to FIGS. 5A and 5B, which illustrate schematic diagrams of an exemplary apex of emitter tip cleaned using a localized optical radiation heating mechanism, consistent with embodiments of the present disclosure. FIGS. 5A and 5B illustrate an apex 536 of an emitter tip 535, one or more contaminants 520 bonded to a surface of emitter tip 535, and an optical beam 545 illuminating a portion of apex 536. It is to be appreciated that emitter tip 535 and apex 536 may be substantially similar to and may perform substantially similar functions as emitter tip 335 and apex 336 of FIG. 3.

In some embodiments, optical beam 545, upon illuminating a portion of apex 536, may break the bond between one or more contaminants 520 and the surface of emitter tip 535. Breaking the bond between contaminant 520 and a surface of emitter tip 535 to clean emitter tip 535 may include a localized optical radiation heating mechanism. In this mechanism, optical beam 545 may be focused on apex 536 of emitter tip 535, causing the temperature of apex 536 to rise locally such that one or more contaminants 520 may be desorbed from the surface. In some embodiments, optical beam 545 may comprise a near-infrared laser beam, or a mid-infrared laser beam. The wavelength of optical beam 545 may be chosen based on type of contaminant 520, or nature of the bond formed between contaminant 520 and surface of apex 536. For example, an infrared laser beam having a wavelength of 800 nm may be used to desorb water molecules from apex 536 and a near-infrared laser beam having a wavelength of 1500 nm may be used to remove a carbon monoxide molecule bonded to apex 536. It is to be appreciated that these exemplary wavelengths are non-limiting and non-specific. Other laser wavelengths and intensities may be used, as appropriate. Although the local temperature of emitter tip 535 may be increased by exposure to optical beam 545, the temperature rise is significantly less compared to resistive and radiative heating techniques. This is because the heating is localized and confined to the emission surface or apex 536 of emitter tip 535. Additionally, because only a small targeted area (e.g., apex 536) of emitter tip 535 is cleaned, the number of contaminants released may not burden the vacuum pumping mechanism to cause significant reduction in vacuum levels around emitter tip 535. FIG. 5B illustrates a surface of apex 536 of emitter tip 535 substantially devoid of contaminant 520 upon illumination by optical beam 545.

Turning back to FIG. 5A, optical beam 545 may comprise a linearly polarized optical beam such that the electric field 548 oscillates in a direction perpendicular to the propagation of optical beam 545 and substantially parallel to the tapering edge of emitter tip 535. In some embodiments, a surface mode of linearly polarized optical beam 545 may be excited upon illumination of a surface of emitter tip 535. The surface mode of linearly polarized optical beam 545 may comprise a localized surface wave 552. In some embodiments, localized surface wave 552 may enable or facilitate removal of contaminants 420 bonded to the surface of apex 536 of emitter tip 535.

An electron emitter tip cleaning technique using optical beams such as a laser, may have some or all of the advantages discussed herein:
1. High cleaning efficiency—Unlike conventional flash heating techniques which clean the electron emission source including the filament and the emitter tip supported by the filament, using optical beams such as lasers may allow targeting only a small region or area of the emitter tip, typically the apex, to remove contaminants or adsorbates from useful, emitting portions of the emitter tip, rendering the cleaning process more efficient.
2. Low outgassing—Because the optical beams may be targeted and localized to clean only the emitting part of the emitter tip, fewer contaminants are ejected, resulting in low outgassing into the chamber space. The low outgassing may help keep the chamber and emitter tip surfaces clean, thus lowering the vacuum level requirements.
3. High emission-current stability and current-decay time—The field-emission sources rely on high electrostatic fields across the emitter tip to emit electrons. Formation of contaminant layers on the emitter may cause emission current instability and short current-decay times. The emission source cleaning technique using optical beams may allow more frequent cleaning such that the emission current stability is maintained, and current-decay times can be prolonged.
4. Short cleaning periods—Cleaning with optical beams such as lasers is extremely quick and efficient. For example, a cleaning cycle may include an exposure of the emitter tip surface to a laser beam for a few milliseconds or less, because a small area of the emitter tip can be targeted and cleaned at a time.
5. High imaging resolution—The stability in emission current can be maintained and the current-decay times can be extended by frequent and efficient cleaning cycles, improving imaging resolution.
6. High inspection throughput—The emitter tip of the electron source may be cleaned during wafer inspection without shutting the tool down for maintenance, thereby improving the machine-up time, and overall inspection throughput.
7. Cost-effective—The optical beam cleaning technique allows a user to clean the emitter tips with localized heating for very short periods of time, thus mitigating the risk of tip blunting. As a result, the operating lifetime of emitter tips is extended and fewer tip replacements may be needed, which also improves the inspection throughput.

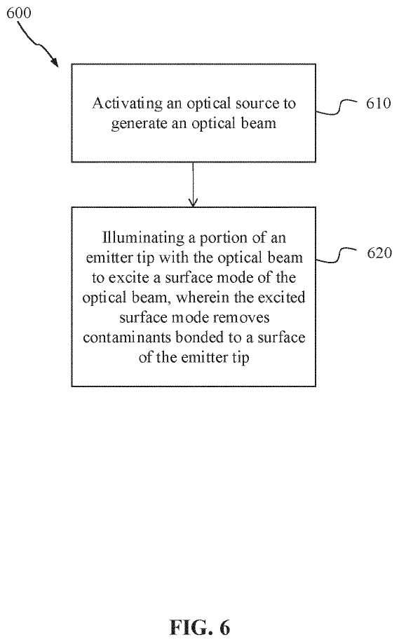

Reference is now made to FIG. 6, which illustrates a process flowchart representing an exemplary method 600 of removing a contaminant from an emitter tip of an electron source, consistent with embodiments of the present disclosure. Method 600 may be performed by controller 50 of EBI system 100, as shown in FIG. 1, for example. Controller 50 may be programmed to implement one or more steps of method 600. For example, controller 50 may activate an optical source to generate an optical beam, adjust the characteristics of the optical beam generated, and carry out other functions.

In step 610, an optical source (e.g., optical source 340 of FIG. 3) such as a laser, may be activated to generate an optical beam (e.g., optical beam 345 of FIG. 3). In some embodiments, a characteristic of the optical beam may be adjusted prior to directing the optical beam towards an electron source. The optical source may be fixedly coupled with a chamber (e.g., chamber 310 of FIG. 3) comprising a view port (e.g., view port 350 of FIG. 3). The optical source may be aligned with the chamber such that the optical beam generated may pass through the view port.

In step 620, the optical beam may be directed to illuminate a portion of an emitter tip (e.g., emitter tip 335 of FIG. 3) to excite a surface mode of the optical beam. The excited surface mode of the optical beam may facilitate removal of one or more contaminants (e.g., contaminant 420 of FIG. 4) bonded or adsorbed to the emitter tip surface. Removing the one or more contaminants may include breaking a bond between the contaminant(s) and the emitter tip surface such that upon breaking, the contaminant(s) is ejected and pumped out of chamber, leaving the surface of emitter tip substantially devoid of contaminants. In some embodiments, the excited surface mode may include a propagating surface wave (e.g., propagating surface wave 452 of FIG. 4A) or a localized surface wave (e.g., localized surface wave 552 of FIG. 5A).

In some embodiments, breaking the bond may include a photon-assisted quantum process, also referred to as photon-contaminant resonance, to remove atoms or molecules from a surface of the emitter tip. A photon-contaminant resonance mechanism for cleaning emitter tips may include adjusting a wavelength of the optical beam comprising photons to break the bond between the contaminant and the surface of emitter tip or apex (e.g., apex 436 of FIG. 4). The wavelength may be adjusted to be resonant with the bond formed between contaminant and surface of emitter tip.

In some embodiments, breaking the bond between the contaminant and a surface of the emitter tip to clean emitter tip may include a localized optical radiation heating mechanism. In this mechanism, the optical beam may be focused on the apex of the emitter tip, causing the temperature of the apex to rise locally such that one or more contaminants may be desorbed from the surface. In some embodiments, optical beam may comprise a near-infrared laser beam, or a mid-infrared laser beam.

A non-transitory computer readable medium may be provided that stores instructions for a processor of a controller (e.g., controller 50 of FIG. 1) to carry out image inspection, image acquisition, activate optical source, regulate pumping mechanism and pumps, direct the optical beam to be incident on the emitter tip of an electron source, adjusting a wavelength or other beam characteristic of the optical beam, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments of the present disclosure may further be described using the following clauses:
1. An electron beam apparatus comprising:
an electron source comprising an emitter tip configured to emit electrons;
an optical source configured to generate an optical beam illuminating a portion of the emitter tip to excite a surface mode of the optical beam, wherein the excited surface mode facilitates removal of a contaminant from a surface of the illuminated portion of the emitter tip.
2. The electron beam apparatus of claim 1, further comprising a chamber enclosing the electron source, the chamber comprising a view port configured to allow the optical beam to pass through.
3. The electron beam apparatus of clause 2, wherein the optical source is coupled with the chamber such that the generated optical beam travels through the view port towards the emitter tip.
4. The electron beam apparatus of any one of clauses 1-3, wherein the illumination of the emitter tip by the optical beam causes a breakage of a bond between the contaminant and the surface of the emitter tip.
5. The electron beam apparatus of clause 4, wherein illumination of the emitter tip by the optical beam causes breakage of the bond assisted by a photon-assisted quantum process.
6. The electron beam apparatus of clause 4, wherein illumination of the emitter tip by the optical beam causes breakage of the bond assisted by localized heating of the emitter tip.
7. The electron beam apparatus of clause 4, wherein illumination of the emitter tip by the optical beam causes breakage of the bond assisted by a combination of a photon-assisted quantum process and localized heating of the emitter tip.
8. The electron beam apparatus of any one of clauses 1-7, wherein a wavelength of the optical beam illuminating the portion of the emitter tip is adjusted based on the contaminant to be removed.
9. The electron beam apparatus of clause 8, wherein the wavelength of the optical beam is further adjusted based on a bond energy of the contaminant.
10. The electron beam apparatus of any one of clauses 8 and 9, wherein illumination of the emitter tip by the optical beam causes a temperature of the emitter tip to increase, and wherein the temperature of the emitter tip is influenced by the wavelength of the optical beam.
11. The electron beam apparatus of any one of clauses 1-10, wherein the contaminant comprises an atom, a molecule, or a gas molecule.
12. The electron beam apparatus of any one of clauses 1-11, wherein the contaminant is adsorbed on the surface of the emitter tip or bonded to the surface of the emitter tip.
13. The electron beam apparatus of any one of clauses 1-12, wherein the optical source comprises a laser source.
14. The electron beam apparatus of any one of clauses 1-13, wherein the optical beam comprises a continuous laser beam or a pulsed laser beam.
15. The electron beam apparatus of any one of clauses 1-14, wherein the electron source comprises a cold field emitter or a field-emission source.
16. The electron beam apparatus of any one of clauses 2-15, further comprising a vacuum pumping mechanism in fluidic connection with the chamber and configured to evacuate the removed contaminant from the chamber, the pumping mechanism comprising a plurality of vacuum pumps.
17. The electron beam apparatus of any one of clauses 1-16, wherein the emitter tip comprises a grating structure.
18. The electron beam apparatus of clause 17, wherein a characteristic of the grating structure matches a wavevector of the optical beam.
19. The electron beam apparatus of any one of clauses 1-18, wherein the surface mode comprises a propagating surface wave or a localized surface wave.
20. The electron beam apparatus of any one of clauses 1-19, wherein the optical beam is linearly polarized.
21. A method of removing a contaminant from an emitter tip of an electron source, the method comprising:
activating an optical source to generate an optical beam; and
illuminating a portion of the emitter tip with the optical beam to excite a surface mode of the optical beam, wherein the excited surface mode facilitates removal of the contaminant bonded to a surface of the illuminated portion of the emitter tip.
22. The method of clause 21, wherein illuminating the portion of the emitter tip comprises directing the optical beam through a view port of a chamber enclosing the electron source.
23. The method of clause 22, further comprising coupling the optical source with the chamber such that the generated optical beam travels through the view port towards the emitter tip.
24. The method of any one of clauses 21-23, wherein illuminating the portion of the emitter tip causes a bond to be broken between the contaminant and the surface of the emitter tip.
25. The method of clause 24, wherein the breaking of the bond is assisted by a photon-assisted quantum process.
26. The method of clause 24, wherein the breaking of the bond is assisted by locally heating the illuminated portion of the emitter tip.
27. The method of clause 24, wherein the breaking of the bond is assisted by a combination of the photon-assisted quantum process and locally heating the illuminated portion of the emitter tip.
28. The method of any one of clauses 21-27, further comprising adjusting a wavelength of the optical beam illuminating the portion of the emitter tip based on the contaminant to be removed.
29. The method of clause 28, comprising further adjusting the wavelength of the optical beam based on a bond energy of the contaminant.
30. The method of any one of clauses 28 and 29, wherein illuminating the portion of the emitter tip with the optical beam increases a temperature of the emitter tip, and wherein the temperature of the emitter tip is influenced by the wavelength of the optical beam.
31. The method of any one of clauses 21-30, wherein the contaminant comprises an atom, a molecule, or a gas molecule.
32. The method of any one of clauses 21-31, wherein the contaminant is adsorbed on the surface of the emitter tip or bonded to the surface of the emitter tip.
33. The method of any one of clauses 31-32, wherein the optical source comprises a laser source.
34. The method of any one of clauses 21-33, wherein the optical beam comprises a continuous laser beam or a pulsed laser beam.
35. The method of any one of clauses 21-34, wherein the electron source comprises a cold field emitter or a field-emission source.
36. The method of any one of clauses 22-35, further comprising evacuating, using a vacuum pumping mechanism, the removed contaminant from the chamber, the vacuum pumping mechanism comprising a plurality of vacuum pumps.
37. The method of any one of clauses 21-36, wherein the emitter tip comprises a grating structure.
38. The method of clause 37, wherein a characteristic of the grating structure matches a wavevector of the optical beam.
39. The method of any one of clauses 21-38, wherein the surface mode comprises a propagating surface wave or a localized surface wave.
40. The method of any one of clauses 21-39, further comprising linearly polarizing the optical beam.
41. A non-transitory computer readable medium storing a set of instructions that is executable by one or more processors of an electron beam apparatus to cause the electron beam apparatus to perform a method of removing a contaminant from an emitter tip of an electron source, the method comprising:
activating an optical source to generate an optical beam; and
illuminating a portion of the emitter tip with the optical beam to excite a surface mode of the optical beam, wherein the excited surface mode facilitates removal of the contaminant bonded to a surface of the illuminated portion of the emitter tip.
42. The non-transitory computer readable medium of clause 41, wherein illuminating the portion of the emitter tip comprises directing the optical beam through a view port of a chamber enclosing the electron source.
43. The non-transitory computer readable medium of clause 42, wherein the set of instructions that is executable by one or more processors of the electron beam apparatus causes the electron beam apparatus to further perform coupling the optical source with the chamber such that the generated optical beam travels through the view port towards the emitter tip.
44. The non-transitory computer readable medium of any one of clauses 41-43, wherein illuminating the portion of the emitter tip causes a bond to be broken between the contaminant and the surface of the emitter tip.
45. The non-transitory computer readable medium of clause 44, wherein the breaking of the bond is assisted by a photon-assisted quantum process.
46. The non-transitory computer readable medium of clause 44, wherein the breaking of the bond is assisted by locally heating the illuminated portion of the emitter tip.
47. The non-transitory computer readable medium of clause 44, wherein the breaking of the bond is assisted by a combination of a photon-assisted quantum process and locally heating the illuminated portion of the emitter tip.
48. The non-transitory computer readable medium of any one of clauses 41-47, wherein the set of instructions that is executable by one or more processors of the electron beam apparatus causes the electron beam apparatus to further perform adjusting a wavelength of the optical beam illuminating the portion of the emitter tip based on the contaminant to be removed.
49. The non-transitory computer readable medium of clause 48, comprising further adjusting the wavelength of the optical beam based on a bond energy of the contaminant.
50. The non-transitory computer readable medium of any one of clauses 48 and 49, wherein illuminating the portion of the emitter tip with the optical beam increases a temperature of the emitter tip, and wherein the temperature of the emitter tip is influenced by the wavelength of the optical beam.
51. The non-transitory computer readable medium of any one of clauses 41-50, wherein the contaminant comprises an atom, a molecule, or a gas molecule.
52. The non-transitory computer readable medium of any one of clauses 41-51, wherein the contaminant is adsorbed on the surface of the emitter tip or bonded to the surface of the emitter tip.
53. The non-transitory computer readable medium of any one of clauses 41-52, wherein the optical source comprises a laser source.
54. The non-transitory computer readable medium of any one of clauses 41-53, wherein the optical beam comprises a continuous laser beam or a pulsed laser beam.
55. The non-transitory computer readable medium of any one of clauses 41-54, wherein the electron source comprises a cold field emitter or a field-emission source.
56. The non-transitory computer readable medium of any one of clauses 42-55, wherein the set of instructions that is executable by one or more processors of the electron beam apparatus causes the electron beam apparatus to further perform evacuating, using a vacuum pumping mechanism, the removed contaminant from the chamber, the vacuum pumping mechanism comprising a plurality of vacuum pumps.
57. The non-transitory computer readable medium of any one of clauses 41-56, wherein the emitter tip comprises a grating structure.
58. The non-transitory computer readable medium of clause 57, wherein a characteristic of the grating structure matches a wavevector of the optical beam.
59. The non-transitory computer readable medium of any one of clauses 41-58, wherein the surface mode comprises a propagating surface wave or a localized surface wave.
60. The non-transitory computer readable medium of any one of clauses 42-55, wherein the set of instructions that is executable by one or more processors of the electron beam apparatus causes the electron beam apparatus to further perform linearly polarizing the optical beam.
61. An electron beam apparatus comprising:
an electron source comprising an emitter tip configured to emit electrons;
an optical source configured to generate an optical beam illuminating a portion of the emitter tip to remove a contaminant from a surface of the illuminated portion of the emitter tip.
62. The electron beam apparatus of clause 61, further comprising a chamber enclosing the electron source, the chamber comprising a view port configured to allow the optical beam to pass through.
63. The electron beam apparatus of clause 62, wherein the optical source is coupled with the chamber such that the generated optical beam travels through the view port towards the emitter tip.
64. The electron beam apparatus of any one of clauses 61-63, wherein the illumination of the emitter tip by the optical beam causes a breakage of a bond between the contaminant and the surface of the emitter tip.
65. The electron beam apparatus of clause 64, wherein illumination of the emitter tip by the optical beam causes breakage of the bond assisted by a photon-assisted quantum process.
66. The electron beam apparatus of clause 64, wherein illumination of the emitter tip by the optical beam causes breakage of the bond assisted by localized heating of the emitter tip.
67. The electron beam apparatus of clause 64, wherein illumination of the emitter tip by the optical beam causes breakage of the bond assisted by a combination of a photon-assisted quantum process and the localized heating.
68. The electron beam apparatus of any one of clauses 61-67, wherein a wavelength of the optical beam illuminating the portion of the emitter tip is adjusted based on the contaminant to be removed.
69. The electron beam apparatus of clause 68, wherein the wavelength of the optical beam is further adjusted based on a bond energy of the contaminant.
70. The electron beam apparatus of any one of clauses 68 and 69, wherein illumination of the emitter tip by the optical beam causes a temperature of the emitter tip to increase, and wherein the temperature of the emitter tip is influenced by the wavelength of the optical beam.
71. The electron beam apparatus of any one of clauses 61-70, wherein the contaminant comprises an atom, a molecule, or a gas molecule.
72. The electron beam apparatus of any one of clauses 61-71, wherein the contaminant is adsorbed on the surface of the emitter tip or bonded to the surface of the emitter tip.
73. The electron beam apparatus of any one of clauses 61-72, wherein the optical source comprises a laser source.
74. The electron beam apparatus of any one of clauses 61-73, wherein the optical beam comprises a continuous laser beam or a pulsed laser beam.
75. The electron beam apparatus of any one of clauses 61-74, wherein the electron source comprises a cold field emitter or a field-emission source.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the technology disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. An electron beam apparatus comprising:
an electron source comprising an emitter tip configured to emit electrons;
an optical source configured to generate an optical beam illuminating a portion of the emitter tip to excite a surface mode of the optical beam, wherein the excited surface mode facilitates removal of a contaminant from a surface of the illuminated portion of the emitter tip.

2. The electron beam apparatus of claim 1, further comprising a chamber enclosing the electron source, the chamber comprising a view port configured to allow the optical beam to pass through.

3. The electron beam apparatus of claim 1, wherein the illumination of the emitter tip by the optical beam causes a breakage of a bond between the contaminant and the surface of the emitter tip.

4. The electron beam apparatus of claim 3, wherein the illumination of the emitter tip by the optical beam causes breakage of the bond assisted by a photon-assisted quantum process.

5. The electron beam apparatus of claim 3, wherein the illumination of the emitter tip by the optical beam causes breakage of the bond assisted by localized heating of the emitter tip.

6. The electron beam apparatus of claim 3, wherein the illumination of the emitter tip by the optical beam causes breakage of the bond assisted by a combination of a photon-assisted quantum process and localized heating of the emitter tip.

7. The electron beam apparatus of any one of claim 1, wherein a wavelength of the optical beam illuminating the portion of the emitter tip is adjusted based on the contaminant to be removed.

8. The electron beam apparatus of claim 7, wherein the wavelength of the optical beam is further adjusted based on a bond energy of the contaminant.

9. The electron beam apparatus of claim 7, wherein illumination of the emitter tip by the optical beam causes a temperature of the emitter tip to increase, and wherein the temperature of the emitter tip is influenced by the wavelength of the optical beam.

10. The electron beam apparatus of any one of claim 1, wherein the contaminant comprises an atom, a molecule, or a gas molecule.

11. The electron beam apparatus of claim 1, wherein the contaminant is adsorbed on the surface of the emitter tip or bonded to the surface of the emitter tip.

12. The electron beam apparatus of claim 1, wherein the emitter tip comprises a grating structure, and wherein a characteristic of the grating structure matches a wavevector of the optical beam.

13. The electron beam apparatus of claim 1, wherein the surface mode comprises a propagating surface wave or a localized surface wave.

14. The electron beam apparatus of claim 1, wherein the optical beam is linearly polarized.

15. A non-transitory computer readable medium storing a set of instructions that is executable by one or more processors of an electron beam apparatus to cause the electron beam apparatus to perform a method of removing a contaminant from an emitter tip of an electron source, the method comprising:
activating an optical source to generate an optical beam; and
illuminating a portion of the emitter tip with the optical beam to excite a surface mode of the optical beam, wherein the excited surface mode facilitates removal of the contaminant bonded to a surface of the illuminated portion of the emitter tip.

16. The non-transitory computer readable medium of claim 15, wherein illuminating the portion of the emitter tip comprises directing the optical beam through a view port of a chamber enclosing the electron source.

17. The non-transitory computer readable medium of claim 16, wherein the set of instructions that is executable by one or more processors of the electron beam apparatus causes the electron beam apparatus to further perform coupling the optical source with the chamber such that the generated optical beam travels through the view port towards the emitter tip.

18. The non-transitory computer readable medium of claim 15, wherein illuminating the portion of the emitter tip causes a bond to be broken between the contaminant and the surface of the emitter tip.

19. The non-transitory computer readable medium of claim 18, wherein the breaking of the bond is assisted by a photon-assisted quantum process.

20. An electron beam apparatus comprising:
an electron source comprising an emitter tip configured to emit electrons; and
an optical source configured to generate an optical beam illuminating a portion of the emitter tip to remove a contaminant from a surface of the illuminated portion of the emitter tip.
